(19) United States
(12) Patent Application Publication
(10) Pub. No.: US 2010/0157540 A1
(43) Pub. Date: Jun. 24, 2010

(54) FIN-TYPE HEAT SINK AND ELECTRONIC DEVICE USING SAME

(75) Inventors: FANG-XIANG YU, Shenzhen City (CN); JER-HAUR KUO, Tu-Cheng (TW)

Correspondence Address: PCE INDUSTRY, INC.;ATT. Steven Reiss, 288 SOUTH MAYO AVENUE, CITY OF INDUSTRY, CA, 91789, US

(73) Assignees: FU ZHUN PRECISION INDUSTRY (SHEN ZHEN) CO., LTD., Shenzhen City (CN); FOXCONN TECHNOLOGY CO., LTD., Tu-Cheng (TW)

(21) Appl. No.: 12/489,428

(22) Filed: Jun. 23, 2009

(30) Foreign Application Priority Data
Dec. 22, 2008 (CN) 200810306424.5

(51) Int. Cl. H05K 7/20; F28F 7/00

(52) U.S. Cl. 361/710; 361/707; 165/185

(57) ABSTRACT

A heat sink includes two heat spreaders spaced from each other and a plurality of heat dissipation fins connected between the two heat spreaders. The heat dissipation fin is wave-shaped from one of the heat spreaders to the other one of the heat spreaders. The heat dissipation fins are spaced from each other. When a force is applied to two heat spreaders of the heat sink, the heat dissipation fin is resiliently deformed to change a distance between the two heat spreaders. The present disclosure also discloses an electronic device incorporating the heat sink and the heat dissipation fin.

### BACKGROUND

1. Technical Field

The present disclosure relates to heat sinks, and particularly to a heat sink with flexible heat dissipation fins and having a good adaptability to different electronic devices.

2. Description of Related Art

With continuing development of the electronic technology, electronic components such as CPUs (central processing units) generate more and more heat required to be dissipated immediately. Conventionally, heat sinks are used to remove the heat generated by the electronic components.

A typical heat sink includes a base and a plurality of heat dissipation fins extending upwardly and perpendicularly from the base. The heat dissipation fins are flat-shaped and rigid. A size of the heat sink can not be changed in use unless be destroyed. However, different electronic devices usually have different shapes and sizes, and thus a space of each electronic device for accommodating the heat sink is different from that of other electronic devices. Therefore, the heat sink with a changeless size can only be used in one special electronic device, which causes an inferior adaptability to the heat sink.

For the said reasons, a heat sink which can overcome the described shortcomings is desired.

### BRIEF DESCRIPTION OF THE DRAWINGS

Many aspects of the embodiments can be better understood with references to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of a heat sink according to a first embodiment of the present disclosure.

FIG. 2 is an isometric view of a heat dissipation fin of the heat sink of FIG. 1.

FIG. 3 is a schematic view of an electronic device incorporating the heat sink of FIG. 1.

FIG. 4 is a schematic view of an electronic device incorporating the heat dissipation fin of FIG. 2.

FIG. 5 is a side view of a heat dissipation fin of a heat sink according to a second embodiment of the present disclosure.

FIG. 6 is an isometric view of a heat dissipation fin of a heat sink according to a third embodiment of the present disclosure.

### DETAILED DESCRIPTION

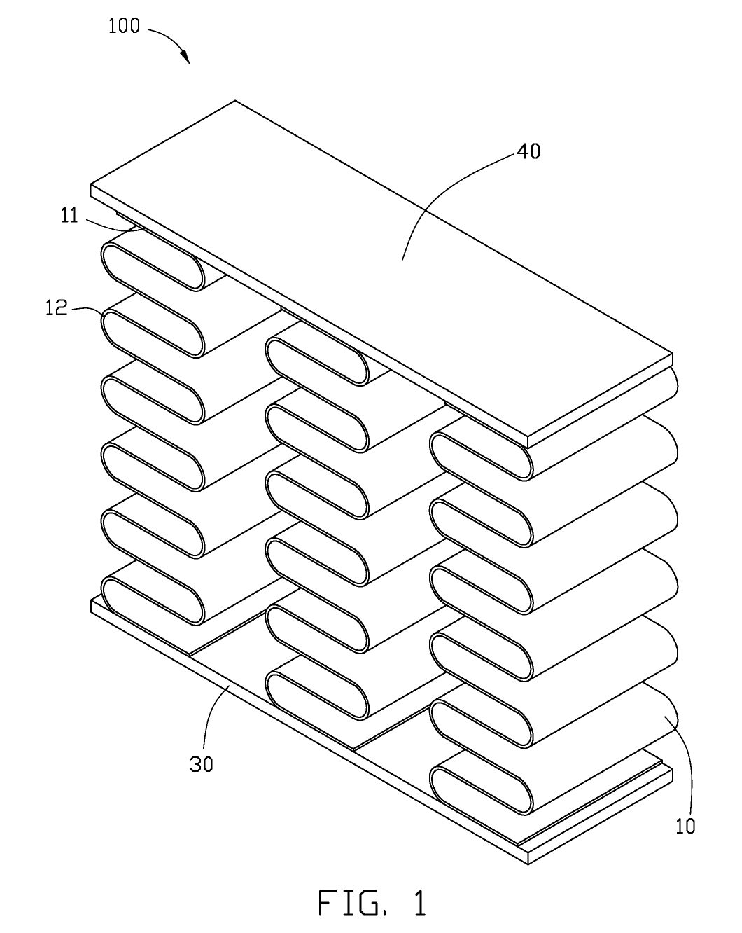

Referring to FIG. 1, a heat sink 100 according to a first embodiment of the present disclosure includes a first heat spreader 30, a second heat spreader 40 spaced from the first heat spreader 30, and a plurality of heat dissipation fins 10 connected between the first and second heat spreaders 30, 40. The heat dissipation fins 10 are spaced from each other and each are folded to have a round wave-shaped configuration. The first and second heat spreaders 30, 40 are made of thermal conductive materials, such as copper, aluminum, etc. The heat dissipation fins 10 are made of thermal conductive and pliable material, such as aluminum or aluminous alloy.

Each of the heat spreaders 30, 40 is substantially a rectangular plate. The first heat spreader 30 faces to and is parallel to the second heat spreader 40.

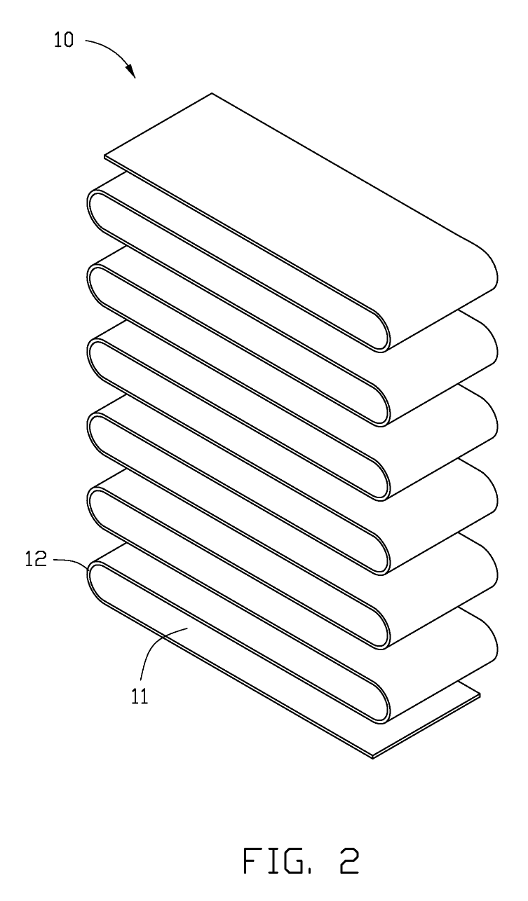

Referring to FIG. 2, each of the heat dissipation fins 10 is formed by a sheet bent alternately leftwards and rightwards to form a folded, wavy shape between the heat spreaders 30, 40. The heat dissipation fin 10 includes a plurality of flat portions 11 evenly spaced from each other and a plurality of curved connecting portions 12 positioned between every two neighboring flat portions 11. The flat potions 11 are parallel to the first and second heat spreaders 30, 40. Each of the flat portions 11 is substantially rectangular, and has two connecting portions 12 positioned at two opposite lateral sides, i.e., left and right sides thereof, in which one connecting portion 12 at the left side connecting the flat portion 11 with the left side of one neighboring flat portion 11, and the other connecting portion 12 at the right side connecting the flat portion 11 with the right side of another neighboring flat portion 11. Two flat portions 11 at topmost and bottommost ends of each heat dissipation fin 10 are respectively attached to the first and second heat spreaders 30, 40. Preferably, the topmost and bottommost flat portions 11 of each heat dissipation fin 10 are welded on the first and second heat spreaders 30, 40, respectively. Alternatively, the heat spreaders 30, 40 can also be integrally formed with the heat dissipation fins 10. When a force is applied to the heat spreaders 30, 40 of the heat sink 100, the heat dissipation fins 10 can generate resilient deformations to change a distance between the heat spreaders 30, 40.

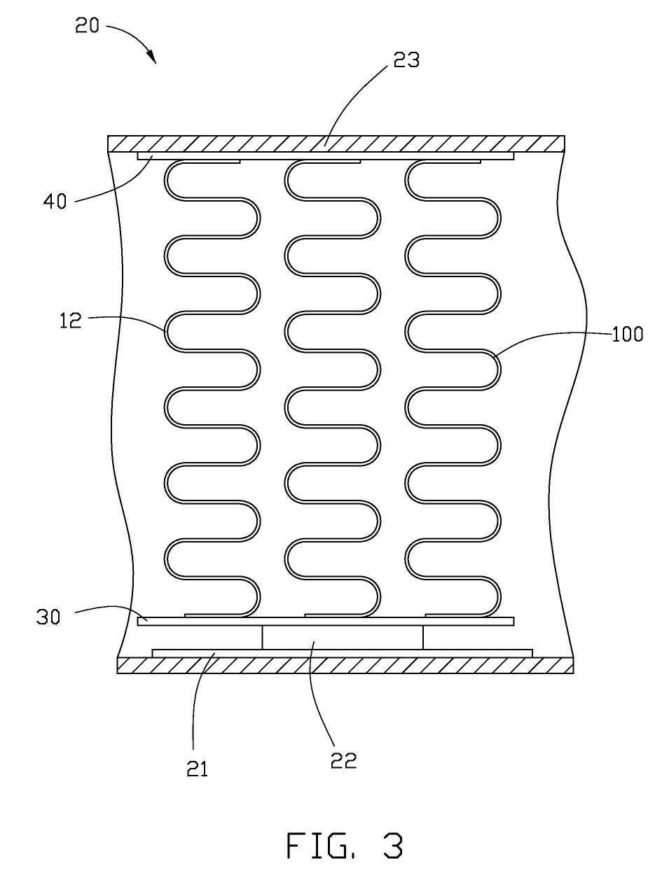

Referring to FIG. 3, an electronic device 20 incorporating the heat sink 100 is shown. The electronic device 20 may be a computer, a projector, etc. The electronic device 20 includes a shell 23, a printed circuit board 21 secured on an inner surface of the shell 23, and an electronic component 22 mounted on the printed circuit board 21, such as a CPU, a north bridge, etc. The electronic component 22 generates heat during operation. The heat sink 100 is received in the shell 23 and secured on the electronic component 22. The first heat spreader 30 of the heat sink 100 is attached to the electronic component 22 and acts as a heat absorber to absorb the heat of the electronic component 22. In this embodiment, the inner space of the shell 23 is narrow, with a height being a little smaller than that of the heat sink 100 at a free state. Since the heat dissipation fins 10 can be resiliently compressed, the heat sink 100 is compressed along a direction perpendicular to the heat spreaders 30, 40 to reduce a height of the heat sink 100. Thus the heat sink 100 can be mounted into the narrow inner space of the electronic device 20. The second heat spreader 40 is resiliently pushed by the deformed heat dissipation fins 10 to abut against an inner surface of the shell 23 at a side opposite to the printed circuit board 21. Thus, when the heat of the electronic component 22 is transferred to the heat dissipation fins 10 through the first heat spreader 30, the heat of the heat dissipation fins 10 can be transferred to the shell 23 via the second heat spreader 40 and then dissipated to ambient air directly via the shell 23, which enables the shell 23 to function as an auxiliary component for the heat dissipation of the electronic component 22.

Contrarily, if the inner space of the shell 23 is big with a height larger than that of the heat sink 100 at a free state, the heat sink 100 should be stretched along the direction perpendicular to the heat spreaders 30, 40 to increase the height of the heat sink 100. In this situation, fastening means such as screws, adhesive, clip, etc is required to securely attach the first heat spreader 30 to the electronic component 22 and the second heat spreader 40 to the shell 23. Thus, the second heat spreader 40 can abut the inner surface of the shell 23 for transferring the heat to the shell 23.

Moreover, the heat sink 100 connected between the shell 23 and the printed circuit board 21 can deform to act as a buffer to reduce an impact of force on the electronic component 22 when the electronic device 20 is subject to an unexpected external force or a vibration, thus to protect the electronic component 22 from a possible damage.

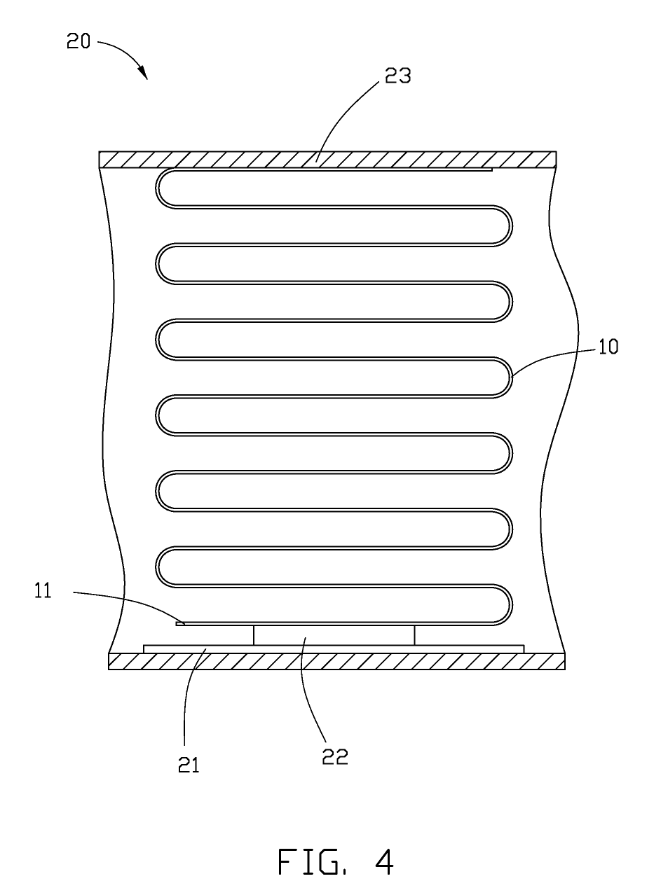

Understandably, the heat dissipation fin 10 can be attached to the electronic component 22 directly for heat dissipation. Referring to FIG. 4, the electronic device 20 incorporating a heat dissipation fin 10 is shown. The flat portion 11 at bottommost end of the heat dissipation fin 10 is attached to the electronic component 22 and acts as a heat absorber to absorb the heat of the electronic component 22, and the flat portion 11 at the topmost end of the heat dissipation fin 10 is attached to the shell 23 opposite to the electronic component 22. When a height of the heat dissipation fin 10 does not conform to a height of the space of the electronic device 20 for accommodating the heat dissipation fin 10, a force can be applied to the flat portions 11 at outmost ends of the heat dissipation fin 10 to change the height of the heat dissipation fin 10, whereby the heat dissipation fin 10 can be used in different electronic devices with different heights.

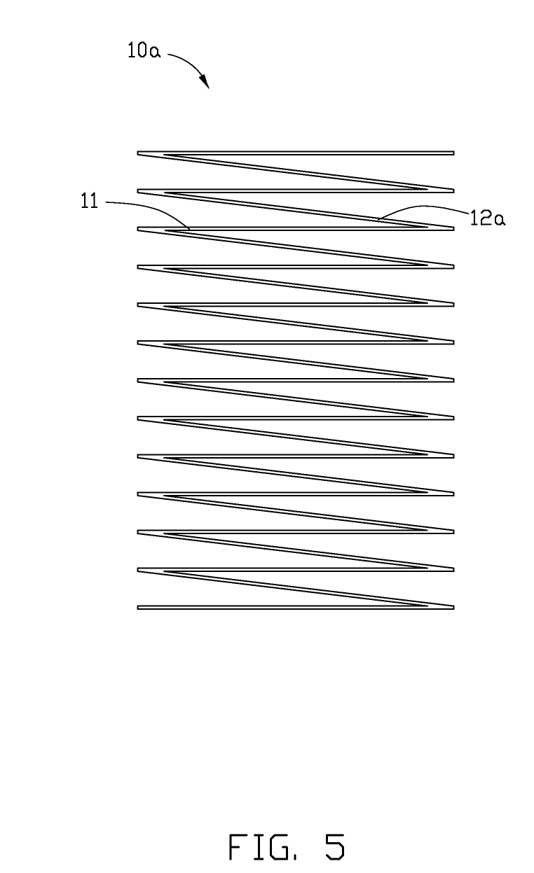

FIG. 5 shows a heat dissipation fin 10a of a heat sink according to a second embodiment of the present disclosure, differing from the previous heat dissipation fin 10 in that the heat dissipation fin 10a in this embodiment has a configuration of a substantially saw-toothed wave. The heat dissipation fin 10a includes a plurality of flat portions 11 parallel to and spaced from each other, and a plurality of connecting portions 12a slantways interconnecting every two neighboring flat portions 11 at two opposite sides of the two neighboring flat portions 11. The connecting portions 12a are substantially flat and parallel to each other.

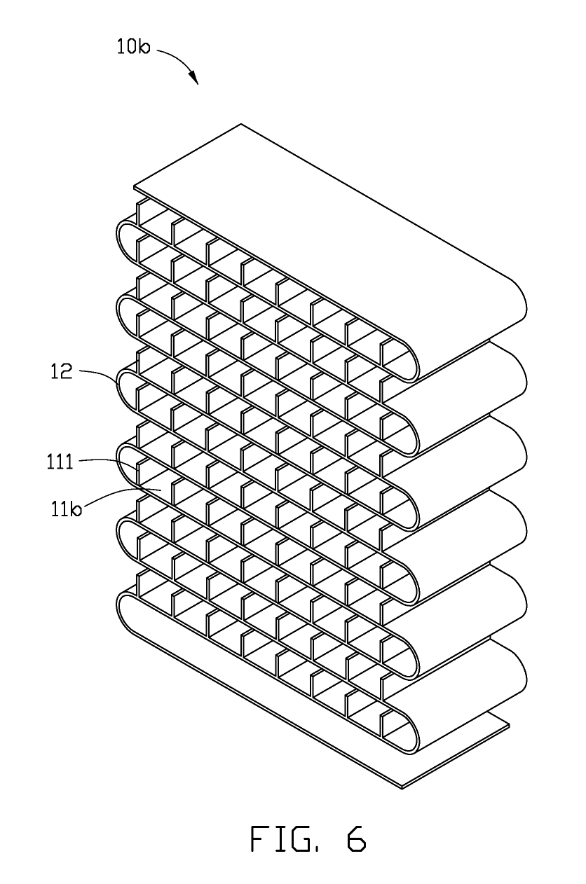

FIG. 6 shows a heat dissipation fin 10b of a heat sink according to a third embodiment of the present disclosure. Similar to the previous heat dissipation fin 10, the heat dissipation fin 10b includes a plurality of flat portions 11b and a plurality of curved connecting portions 12. The difference therebetween is that the heat dissipation fin 10b has a plurality of projections 111 formed on each of the flat portions 11b. Each of the projections 111 has a configuration of a rectangular flake and extends perpendicularly from an upper surface of a flat portion 11b towards a neighboring upper flat portion 11b. A height the projection 111 extending from the flat portion 11b is less than a distance between every two neighboring flat portions 11b. A length of each projection 111 is equal to that of the flat portion 11b between a front side and a rear side of the flat portion 11b. The projections 111 are evenly spaced from each other for increasing a heat dissipation area of the heat dissipation fin 10b.

It is to be understood that even though numerous characteristics and advantages of the disclosure have been set forth in the foregoing description, together with details of the structure and function of the embodiments, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A heat sink comprising:
two heat spreaders spaced from each other; and
a plurality of heat dissipation fins connected between the two heat spreaders, the heat dissipation fins being spaced from each other, each of the heat dissipation fins being folded into a wavy shape from one of the heat spreaders to the other one of the heat spreaders, each of the heat dissipation fins being resiliently deformable so that a distance between the two heat spreaders is changeable when the heat spreaders are subject to one of stretching and compressing forces.

2. The heat sink of claim 1, wherein each of the heat dissipation fins comprises a plurality of flat portions spaced from each other and a plurality of connecting portions positioned between every two neighboring flat portions, the flat portions are parallel to the heat spreaders, the flat portions at topmost and bottommost ends of each heat dissipation fin are respectively attached to the two heat spreaders.

3. The heat sink of claim 2, wherein each of the connecting portions is curved and connects two neighboring flat portions at a same side of the two neighboring flat portions.

4. The heat sink of claim 2, wherein each of the connecting portions is flat and slantways connects two neighboring flat portions at two opposite sides of the two neighboring flat portions.

5. The heat sink of claim 2, wherein a plurality of projections extend from each of the flat portions towards a neighboring flat portion, and a height of each of the projections extending from each of the flat portions is less than a distance between each of the flat portions and the neighboring flat portion.

6. The heat sink of claim 5, wherein the projections are rectangular flake-shaped and spaced from each other.

7. The heat sink of claim 1, wherein each of the heat dissipation fins is made of thermal conductive and pliable material.

8. An electronic device comprising:
a shell;
an electronic component mounted in the shell; and
a heat sink received in the shell and mounted on the electronic component to absorb heat therefrom;
wherein the heat sink comprises two heat spreaders spaced from each other, and a plurality of heat dissipation fins connected between the two heat spreaders, the heat dissipation fins being spaced from each other, each of the heat dissipation fins forming a wavy shape from one of the heat spreaders to the other one of the heat spreaders, each of the heat dissipation fins being resiliently deformable whereby a distance between the two heat spreaders is changeable; and
the two heat spreaders are respectively attached to the electronic component and the shell.

9. The electronic device of claim 8, wherein each of the heat dissipation fins comprises a plurality of flat portions spaced from each other and a plurality of connecting portions positioned between every two neighboring flat portions, the flat portions are parallel to the heat spreaders, and the flat portions at topmost and bottommost ends of the heat dissipation fin are respectively attached to the two heat spreaders.

10. The electronic device of claim 9, wherein each of the connecting portions connects two neighboring flat portions at a same side of the two neighboring flat portions.

11. The electronic device of claim 9, wherein each of the connecting portions slantways connects two neighboring flat portions at two opposite sides of the two neighboring flat portions.

12. The electronic device of claim 9, wherein a plurality of projections extends from each of the flat portions towards a neighboring flat portion, a height of each of the projections extending from each of the flat portions is less than a distance between each of the flat portions and the neighboring flat portion.

13. The electronic device of claim 12, wherein the projections are rectangular flake-shaped and spaced from each other.

14. An electronic device comprising:
a shell;
an electronic component mounted in the shell; and
a heat dissipation fin received in the shell and mounted on the electronic component to absorb heat therefrom;
wherein the heat dissipation fin is resiliently deformable and comprises a plurality of flat portions spaced from each other and a plurality of connecting portions interconnecting two neighboring flat portions, two outmost flat portions of the heat dissipation fin being respectively attached to the electronic component and the shell.

15. The electronic device of claim 14, wherein each of the connecting portions connects two neighboring flat portions at a same side of the two neighboring flat portions.

16. The electronic device of claim 14, wherein each of the connecting portions connects two neighboring flat portions at two opposite sides of the two neighboring flat portions.

17. The electronic device of claim 14, wherein a plurality of projections extends from each of the flat portions towards a neighboring flat portion, a height of each of the projections extending from each of the flat portions is less than a distance between two neighboring flat portions.

18. The electronic device of claim 17, wherein the projections are rectangular flake-shaped and spaced from each other.

19. The electronic device of claim 14, wherein the heat dissipation fin is made of thermal conductive and pliable material.
